(19) United States
(12) Patent Application Publication
(10) Pub. No.: US 2026/0344187 A1
(43) Pub. Date: Oct. 29, 2026

(54) DISPLAY PANEL AND DISPLAY DEVICE

(71) Applicant: Xiamen Tianma Display Technology Co., Ltd., Xiamen (CN)

(72) Inventor: Wei CHEN, Xiamen (CN)

(21) Appl. No.: 19/714,699

(22) Filed: Jun. 22, 2026

(30) Foreign Application Priority Data
Apr. 3, 2026 (CN) 202610442963.X

(51) Int. Cl. H10K 59/121; H10D 86/40; H10D 86/60; H10K 59/88

(52) U.S. Cl. CPC H10K 59/1213; H10D 86/423; H10D 86/60; H10K 59/88

(57) ABSTRACT

The present disclosure relates to the field of display technologies. Provided are a display panel and a display device. The display panel includes a substrate and a driving layer located on a side of the substrate. The driving layer includes a dummy hole and a semiconductor structure. The dummy hole extends along a direction perpendicular to a plane of the substrate. The semiconductor structure at least partially surrounds the dummy hole. An inner wall of the dummy hole circumferentially exposes at least a portion of the semiconductor structure. A bottom of the dummy hole is located at an insulating layer on a side of the semiconductor structure close to the substrate. According to the embodiments of the present disclosure, the dark spots at the edges are alleviated, and the performance reliability of the display panel is improved.

### CROSS-REFERENCE TO RELATED APPLICATIONS

The present application claims priority to Chinese Patent Application No. 202610442963.X, filed on Apr. 3, 2026, the content of which is incorporated herein by reference in its entirety.

### TECHNICAL FIELD

The present disclosure relates to the field of display technologies, and in particular, to a display panel and a display device.

### BACKGROUND

Organic light-emitting diode (OLED) display technologies have characteristics of self-luminescence, high contrast, fast response speed, and flexible bendability and is widely applied in electronic products such as mobile phones, televisions, computers, and wearable devices. Existing display panels have a problem of dark spots at the edges, which affects reliability.

### SUMMARY

In view of this, embodiments of the present disclosure provide a display panel and a display device, to solve the problem of dark spots at display edges and improve the reliability.

In a first aspect, an embodiment of the present disclosure provides a display panel including a substrate and a driving layer located on a side of the substrate. The driving layer includes a dummy hole and a semiconductor structure. The dummy hole extends along a direction perpendicular to a plane of the substrate. The semiconductor structure at least partially surrounds the dummy hole. An inner wall of the dummy hole circumferentially exposes at least a portion of the semiconductor structure. A bottom of the dummy hole is located at an insulating layer on a side of the semiconductor structure close to the substrate.

In a second aspect, based on the same inventive concept, an embodiment of the present disclosure also provides a display device, including a display panel provided by any embodiment of the present disclosure.

### BRIEF DESCRIPTION OF DRAWINGS

In order to more clearly illustrate the embodiments of the present disclosure or the technical solutions in the related art, the following briefly describes the accompanying drawings that need to be used in the embodiments or the description of the related art. Obviously, the accompanying drawings in the following description are some embodiments of the present disclosure. For those skilled in the art, any other accompanying drawing may be obtained according to these accompanying drawings without any creative effort.

FIG. 1 is a schematic diagram of a display panel according to an embodiment of the present disclosure;

FIG. 2 is a schematic top view of a position of a dummy hole according to an embodiment of the present disclosure;

FIG. 3 is a schematic top view of a position of another dummy hole according to an embodiment of the present disclosure;

FIG. 4 is a schematic top view of a position of another dummy hole according to an embodiment of the present disclosure;

FIG. 5 is a schematic diagram of another display panel according to an embodiment of the present disclosure;

FIG. 6 is a schematic diagram of another display panel according to an embodiment of the present disclosure;

FIG. 7 is a schematic diagram of a display panel in related art;

FIG. 8 is a schematic diagram of another display panel according to an embodiment of the present disclosure;

FIG. 9 is a schematic diagram of another display panel according to an embodiment of the present disclosure;

FIG. 10 is a schematic diagram of another display panel according to an embodiment of the present disclosure;

FIG. 11 is a partial schematic diagram of another display panel according to an embodiment of the present disclosure;

FIG. 12 is a partial schematic diagram of another display panel according to an embodiment of the present disclosure;

FIG. 13 is a schematic diagram of another display panel according to an embodiment of the present disclosure; and

FIG. 14 is a schematic diagram of a display device according to an embodiment of the present disclosure.

### DESCRIPTION OF EMBODIMENTS

In order to make the purpose, technical solutions and advantages of the embodiments of the present disclosure clearer, the technical solutions in the embodiments of the present disclosure will be described clearly and completely below in conjunction with the drawings in the embodiments of the present disclosure, and it is clear that the embodiments described are some of the embodiments of the present disclosure, rather than all of the embodiments. Based on the embodiments in the present disclosure, all other embodiments obtained by those skilled in the art fall within the protection scope of the present disclosure.

Terms used in the embodiments of the present disclosure are only for the purpose of describing specific embodiments, but not intended to limit the present disclosure. Singular forms of “a/an”, “said” and “the” used in the embodiments of the present disclosure and the appended claims are also intended to include plural forms, unless the context clearly indicates other meanings.

In related art, dummy holes are provided at edge positions of a display panel, the dummy holes are not used for electrical connection, and the dummy holes serve as channels for discharging hydrogen gas in a dehydrogenation process, which can improve transistor performance at the edge positions, thereby enabling transistor characteristics at the edge positions and transistor characteristics at middle positions to be consistent. At present, display panels provided with dummy holes have the problem of dark spots displayed at the edges during reliability tests. By analyzing the reason for generating the display dark spots, it is found that due to a relatively large etching depth of the conventional dummy holes, the edge stress of the holes is relatively large, cracks are easily generated on the sidewalls of the dummy holes, resulting in moisture intrusion and generation of display dark spots.

In order to solve the problem of dark spots displayed at the edges, the present disclosure provides a solution of forming an etching blocking structure at the position of the dummy holes. The etching blocking structure and the conventional insulating layer have different etching rates due to different materials thereof. The etching blocking structure is configured to slow down the etching rate of the dummy holes, thereby reducing the etching depth of the dummy holes and the edge stress of the dummy holes, and thus alleviating the dark spots at display edges.

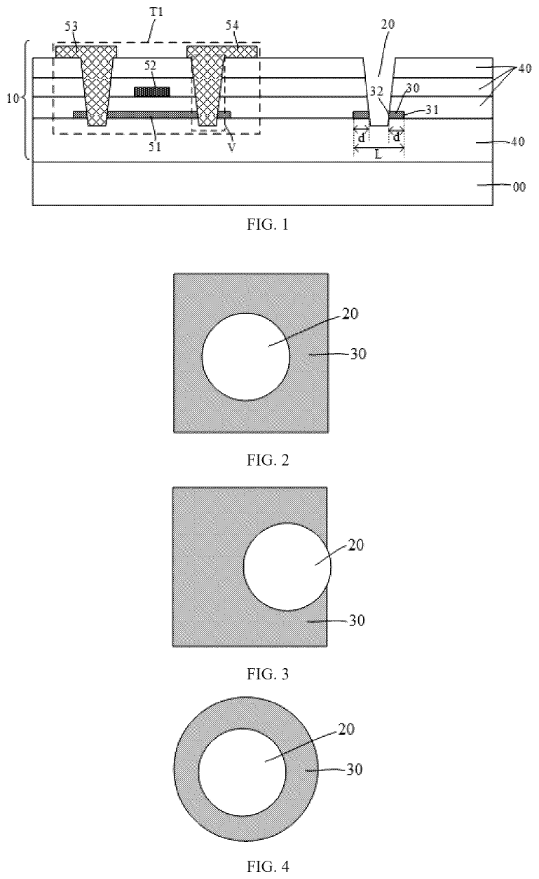

FIG. 1 is a schematic diagram of a display panel according to an embodiment of the present disclosure. FIG. 1 illustrates a film layer at a local position of a display panel. As shown in FIG. 1, the display panel includes a substrate 00 and a driving layer 10 located on a side of the substrate 00. The driving layer 10 includes a dummy hole 20 and a semiconductor structure 30. The dummy hole 20 is not used for electrical connection, and the dummy hole 20 does not belong to functional openings in the circuit structure. The material of the semiconductor structure 30 includes the semiconductor material. The dummy hole 20 extends along a direction perpendicular to a plane of the substrate 00, and the semiconductor structure 30 at least partially surrounds the dummy hole 20. An inner wall of the dummy hole 20 exposes at least a portion of the semiconductor structure 30 in a circumferential direction. A hole bottom of the dummy hole 20 is located at an insulating layer 40 on a side of the semiconductor structure 30 close to the substrate 00. That is, the dummy hole 20 penetrates through the semiconductor structure 30 and a portion of the insulating layer 40 on a side of the semiconductor structure 30 close to the substrate 00, such that the semiconductor structure 30 serves as a partial inner wall of the dummy hole 20.

FIG. 2 is a schematic top view of a position of a dummy hole according to an embodiment of the present disclosure. It can also be seen from FIG. 2 that the semiconductor structure 30 surrounds the dummy hole 20, that is, the inner wall of the dummy hole 20 exposes a circle of the semiconductor structure 30 in the circumferential direction.

FIG. 3 is a schematic top view of a position of another dummy hole according to an embodiment of the present disclosure. FIG. 3 illustrates that the semiconductor structure 30 surrounds a portion of the dummy hole 20, that is, the semiconductor structure 30 exposed by the inner wall of the dummy hole 20 in the circumferential direction does not form a closed ring.

The hole-forming process of the display panel is generally to form an electrical connection hole in a circuit. The dummy hole is usually formed in the original hole-forming process of the display panel. However, in the related art, the dummy hole formed in the hole-forming process may be severely over-etched, thereby resulting in an excessively large depth of the dummy hole, and leading to a risk that the edge of the dummy hole is cracked due to an excessively large stress, and thus causing moisture intrusion to generate dark spots displayed at the edges.

The embodiments of the present disclosure provide a display panel, an inner wall of the dummy hole 20 exposes at least a portion of the semiconductor structure 30 in the circumferential direction, and the bottom of the dummy hole 20 is located at the insulating layer 40 on the side of the semiconductor structure 30 close to the substrate 00. In the hole-forming process for forming the display panel, the rate of etching the semiconductor material is smaller than the rate of etching the insulating layer 40. The semiconductor material is configured as an etching blocking structure. Under the condition that the etching process duration is fixed, the semiconductor material is etched to form the semiconductor structure 30, such that the inner wall of the dummy hole 20 exposes the semiconductor structure 30 circumferentially, thereby reducing the depth of the dummy hole 20 and the edge stress of the dummy hole 20, alleviating the problem of dark spots displayed at the edges caused by cracks at the edges of the dummy hole 20, and thus improving the performance reliability of the display panel.

Exemplarily, FIG. 2 is a top view of the position of the dummy hole 20, which can be understood that the top view direction is parallel to the direction of the orthographic projection on the plane of the substrate 00. In the top view, the semiconductor structure 30 coincides with the orthographic projection of the semiconductor structure 30 on the plane of the substrate 00. It can be seen from FIG. 2 that the orthographic projection of the semiconductor structure 30 on the plane of the substrate 00 is annular. FIG. 2 illustrates an outer edge of the semiconductor structure 30 as a rectangle in the top view.

In some other embodiments, FIG. 4 is a schematic top view of a position of another dummy hole according to an embodiment of the present disclosure. As shown in FIG. 4, the orthographic projection of the semiconductor structure 30 on the plane of the substrate 00 is annular, and the outer edge of the semiconductor structure 30 is circular in the top view.

It should be noted that, in the embodiments of the present disclosure, the shape of the orthographic projection of the semiconductor structure 30 on the plane of the substrate 00 and the shape of the orthographic projection of the dummy hole 20 on the plane of the substrate 00 are all schematic representations, which are not intended to limit the present disclosure.

Exemplarily, as shown in FIG. 1, the semiconductor structure 30 includes an outer edge 31 and an inner edge 32. The outer edge 31 surrounds the inner edge 32. An inner wall of the dummy hole 20 exposes the inner edge 32. Reference can also be made to the positions of the outer edge 31 and the inner edge 32 illustrated in FIG. 2. Along a direction parallel to the plane of the substrate 00, a distance between the outer edge 31 and the inner edge 32 is d, where 0.5 μm≤d≤1 μm. The semiconductor structure 30 is a structure retained after etching the semiconductor material when forming the dummy hole 20 in the hole-forming process. Setting the value range of d to be relatively small can reduce the depth of the dummy hole 20 to alleviate the dark spots at the display edges while reducing the occupation of the wiring space of the display panel.

Exemplarily, as shown in FIG. 1, the semiconductor structure 30 includes an outer edge 31 and an inner edge 32. The outer edge 31 surrounds the inner edge 32. An inner wall of the dummy hole 20 exposes the inner edge 32. Along the direction parallel to the plane of the substrate 00, a dimension of the outer edge 31 is L, where 3.9 μm≤L≤6.8 μm. Such a configuration makes the overall area of the semiconductor structure 30 relatively small, which can reduce the occupation of the wiring space of the display panel while reducing the depth of the dummy hole 20 to alleviate the dark spots at the display edges.

In some embodiments, the material of the semiconductor structure 30 includes silicon or indium gallium zinc oxide.

For example, the display panel includes a first semiconductor structure. The material of the first semiconductor structure includes silicon. The first semiconductor structure has the same material as an active layer of some polysilicon transistors in the circuit.

For example, the display panel includes a second semiconductor structure. The material of the second semiconductor structure includes indium gallium zinc oxide. The second semiconductor structure has the same material as an active layer of some metal oxide transistors in the circuit.

Exemplarily, as shown in FIG. 1, the insulating layer 40 penetrated by the dummy hole 20 is an inorganic insulating layer. The dummy hole 20 may be formed in an original hole-forming process of the display panel. A rate of etching the semiconductor material is smaller than a rate of etching the inorganic insulating layer, thereby enabling the semiconductor material to serve as the etching blocking structure for etching the dummy hole 20. The semiconductor material forms the semiconductor structure 30 after being etched, and an etching depth of the dummy hole 20 is reduced when a hole-forming process duration is fixed.

Exemplarily, FIG. 5 is a schematic diagram of another display panel according to an embodiment of the present disclosure. As shown in FIG. 5, the depth of the dummy hole 20 is h, where 1.5 μm≤h≤1.6 μm. In the embodiments of the present disclosure, the depth h of the dummy hole 20 is configured to enable the dummy hole 20 to penetrate the semiconductor structure 30. The dummy hole 20 can serve as a channel for discharging hydrogen gas in the dehydrogenation process, which can improve the performance of the transistor at the edge position, such that the transistor characteristic at the edge position tends to be consistent with the transistor characteristic at the middle position.

As shown in FIG. 5, the dummy hole 20 includes an orifice on a side away from the substrate 00. Along the direction e perpendicular to the plane of the substrate 00, a distance between the semiconductor structure 30 and the bottom is h1, and a distance between the semiconductor structure 30 and the orifice is h2, where h1<h2. In the embodiments of the present disclosure, the dummy hole 20 penetrates through the semiconductor structure 30 and penetrates through a portion of the insulating layer 40 below the semiconductor structure 30, and h1 is relatively small, such that the overall depth of the dummy hole 20 can be reduced while the dummy hole 20 serves as the hydrogen gas discharge channel.

Exemplarily, as shown in FIG. 5, a distance from the bottom of the dummy hole 20 to the substrate 00 is D, where D>4500 Å.

Exemplarily, FIG. 6 is a schematic diagram of another display panel according to an embodiment of the present disclosure. As shown in FIG. 6, the dummy hole 20 is filled with an insulating material 21. In some embodiments, the insulating material filled in the dummy hole 20 is the organic insulating material.

Exemplarily, as shown in FIG. 1, the driving layer 10 includes a first transistor T1. The first transistor T1 includes a semiconductor active layer 51, a gate electrode 52, a source electrode 53 and a drain electrode 54. At least one of the source electrode 53 and the drain electrode 54 is connected to the semiconductor active layer 51 through an opening V. The semiconductor active layer 51 and the semiconductor structure 30 are located at a same layer, that is, the semiconductor active layer 51 and the semiconductor structure 30 are made of a same material. The opening V extends along the direction perpendicular to the plane of the substrate 00. The semiconductor active layer 51 surrounds the opening V. The inner wall of the opening V exposes a circle of the semiconductor active layer 51 in the circumferential direction. At least one of the source electrode 53 and the drain electrode 54 extends into the opening V to contact the semiconductor active layer 51. FIG. 1 only illustrates that the source electrode 53 and the drain electrode 54 respectively extend into the corresponding holes V to contact the semiconductor active layer 51.

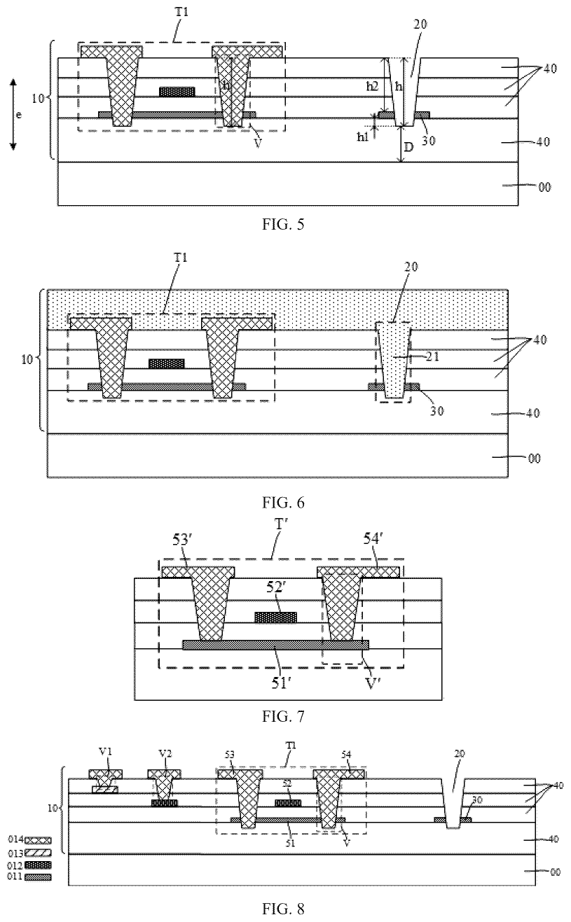

FIG. 7 is a schematic diagram of a display panel in related art, and illustrates a structure of a transistor T′ in the related art. As shown in FIG. 7, in the related art, a source electrode 53′ and a drain electrode 54′ of the transistor T′ are respectively connected to a semiconductor active layer 51′ through holes V′, and the transistor T′ further includes a gate electrode 52′. The holes V′ do not penetrate through the semiconductor active layer 51′, such that the source electrode 53′ and the drain electrode 54′ are respectively in surface contact with the semiconductor active layer 51′ in the corresponding holes V′. During the forming process, the insulating layer is etched in the opening process to form the opening V′, and etching is stopped when reaching the semiconductor active layer 51′. This forming process may cause the flatness and film thickness difference of the semiconductor active layer 51′ at different positions due to the etching uniformity difference, thereby resulting in relatively large differences in the electrical connection performance between the source electrode 53′/drain electrode 54′ and the semiconductor active layer 51′ in different transistors T′, further affecting the characteristic uniformity of the transistors T′ and affecting the display uniformity.

In the embodiments of the present disclosure, the semiconductor active layer 51 in the first transistor T1 surrounds the opening V. The inner wall of the opening V exposes a circle of the semiconductor active layer 51 in the circumferential direction. At least one of the source electrode 53 and the drain electrode 54 extends into the opening V to contact the semiconductor active layer 51. That is, at least one of the source electrode 53 and the drain electrode 54 forms a side contact with the semiconductor active layer 51 within the opening V. In the hole-forming process of forming the display panel, the semiconductor active layer 51 is etched through to form the opening V, and then when the source electrode 53 and the drain electrode 54 are formed, the metal material is filled in the opening V to contact the semiconductor active layer 51 exposed at the inner wall of the opening V. Such a configuration can ensure that the electrical connection performance between the source electrode 53/drain electrode 54 and the semiconductor active layer 51 in the first transistors T1 at different positions tends to be consistent, and can improve the characteristic uniformity of the first transistor T1 at different positions, thereby improving the display uniformity.

In the embodiments of the present disclosure, the semiconductor active layer 51 and the semiconductor structure 30 are located at the same layer, so the semiconductor active layers 51 and the semiconductor structure 30 may be formed in the same process, and the dummy hole 20 and the opening V may be formed in the same hole-forming process. On the one hand, the formed dummy hole 20 can serve as a channel for discharging hydrogen gas in the dehydrogenation process, which can improve the transistor characteristic performance at the edge position, such that the transistor characteristic at the edge position tends to be consistent with the transistor characteristic at the middle position. On the other hand, since the semiconductor structure 30 at least partially surrounds the dummy hole 20, that is, the semiconductor structure 30 is etched through when the dummy hole 20 is formed, such that the semiconductor material in the hole-forming process serves as an etching blocking structure for etching to form the dummy hole 20, the rate of forming the dummy hole 20 is substantially the same as the rate of forming the opening V, thereby reducing the depth of the dummy hole 20, further reducing the edge stress of the dummy hole 20, alleviating the problem of display dark spots caused by cracks at the edge of the dummy hole 20, and thus improving the performance reliability of the display panel.

FIG. 8 is a schematic diagram of another display panel according to an embodiment of the present disclosure. As shown in FIG. 8, the driving layer 10 of the display panel includes a first semiconductor layer 011, a first metal layer 012, a second metal layer 013, and a third metal layer 014. Insulating layers 40 are respectively provided between the first semiconductor layer 011 and the substrate 00, between the first semiconductor layer 011 and the metal layer, and between adjacent metal layers. The semiconductor structure 30 and the semiconductor active layer 51 of the first transistor T1 are located at the first semiconductor layer 011. The gate electrode 52 of the first transistor T1 is located at the first metal layer 012. One plate of the storage capacitor in the pixel circuit is located at the second metal layer 013. The source electrode 53/drain electrode 54 of the first transistor T1 is located at the third metal layer 014. FIG. 8 illustrates that the openings in the driving layer 10 include not only the opening V, but also the first connection opening V1 and/or the second connection opening V2 in the circuit structure. The first connection opening V1 electrically connects a structure located at the third metal layer 014 and a structure located at the second metal layer 013. The second connection opening V2 electrically connects a structure located at the third metal layer 014 and a structure located at the first metal layer 012. The first metal layer 012 and the second metal layer 013 are generally made of metallic molybdenum. Etching rates of the metallic molybdenum and the inorganic insulating layer are greatly different. In some embodiments, the first connection opening V1, the second connection opening V2, the opening V and the dummy hole 20 are formed in the same hole-forming process. In the hole-forming process, the etching for forming the first connection opening V1 stops at the surface of the second metal layer 013, such that surface contact is formed with the second metal layer 013 in the first connection opening V1. Similarly, the etching for forming the second connection opening V2 stops at the surface of the first metal layer 012, such that surface contact is formed with the first metal layer 012 in the second connection opening V2.

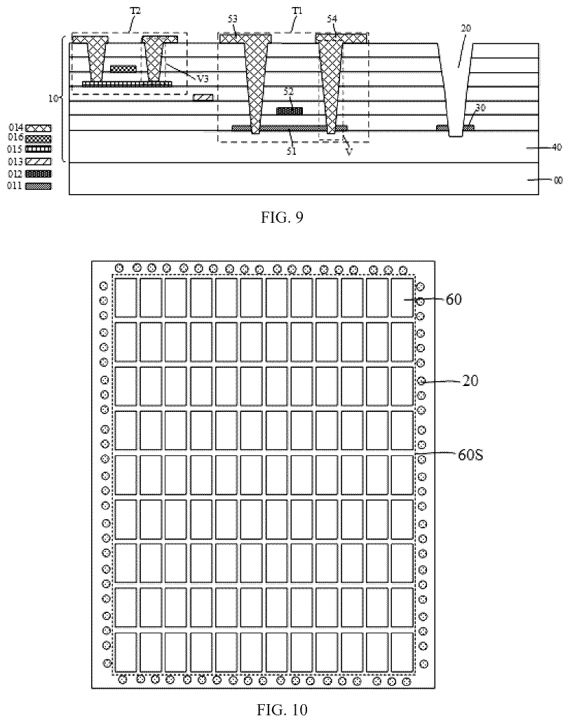

In some other embodiments, FIG. 9 is a schematic diagram of another display panel according to an embodiment of the present disclosure. As shown in FIG. 9, the driving layer 10 includes a first semiconductor layer 011, a first metal layer 012, a second metal layer 013, a second semiconductor layer 015, a fourth metal layer 016, and a third metal layer 014. The driving layer 10 includes a first transistor T1 and a second transistor T2. The semiconductor structure 30 and the semiconductor active layer 51 of the first transistor T1 are located at the first semiconductor layer 011. The gate electrode 52 of the first transistor T1 is located at the first metal layer 012. One plate of the storage capacitor in the pixel circuit is located at the second metal layer 013. The source electrode 53/drain electrode 54 of the first transistor T1 is located at the third metal layer 014. The semiconductor active layer of the second transistor T2 is located at the second semiconductor layer 015, the gate electrode of the second transistor T2 is located at the fourth metal layer 016, and the source electrode/drain electrode of the second transistor T2 is located at the third metal layer 014. It can be seen from FIG. 9 that the source electrode/drain electrode of the second transistor T2 are connected to the second semiconductor layer 015 through a third connection opening V3, and the third connection opening V3 does not penetrate through the second semiconductor layer 015. The source electrode/drain electrode of the second transistor T2 forms surface contact with the second semiconductor layer 015 in the third connection opening V3. In some embodiments, the material of the first semiconductor layer 011 includes silicon, and the material of the second semiconductor layer 015 includes metal oxide.

In some embodiments, the driving layer 10 includes a pixel circuit coupled to a light-emitting device in the display panel. The pixel circuit is configured to drive the light-emitting device to emit light. The pixel circuit may be any structure in the related art. The pixel circuit includes the first transistor T1. For example, a driving transistor in the pixel circuit is the first transistor T1.

In some embodiments, the driving layer 10 includes a shift driving circuit. The shift driving circuit includes a plurality of cascaded shift register units, and an output terminal of the shift register unit is connected to the pixel circuit. The shift register unit may be any structure capable of implementing the signal shift function in the related art. The shift driving circuit includes a first transistor T1.

As shown in FIG. 5, along the direction e perpendicular to the plane of the substrate 00, the depth of the opening V is the same as the depth of the dummy hole 20, the depth of the opening V is h, and the depth of the dummy hole 20 is also h. The dummy hole 20 and the opening V are formed in the same hole-forming process. The configuration of the semiconductor structure 30 in the embodiments of the present disclosure enables the depth of the dummy hole 20 to be substantially the same as the depth of the opening V, which can reduce the depth of the dummy hole 20, thereby reducing the edge stress of the dummy hole 20, alleviating the problem of display dark spots caused by cracks at the edge of the dummy hole 20, and thus improving the performance reliability of the display panel.

In some embodiments, FIG. 10 is a schematic diagram of another display panel according to an embodiment of the present disclosure. As shown in FIG. 10, the display panel includes a plurality of pixel circuits 60 located at the driving layer 10. In the top view shown in FIG. 10, the plurality of pixel circuits 60 are arranged in a pixel circuit array 60S, that is, the plurality of pixel circuits 60 are arranged in an array. A plurality of dummy holes 20 are disposed at the periphery of the pixel circuit array. In FIG. 10, the pixel circuits 60 are only schematically illustrated as block diagrams. The dummy hole 20 serves as a channel for discharging hydrogen gas in the dehydrogenation process to improve the transistor characteristic performance of the pixel circuit 60 at the edge position of the pixel circuit array, thereby enabling the transistor characteristics at the middle position and the edge position of the display panel to be consistent, and thus ensuring the display uniformity.

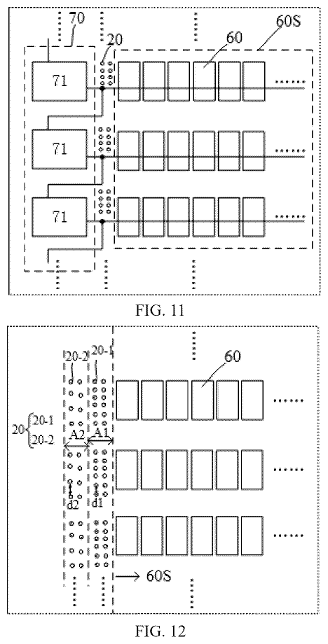

In some embodiments, FIG. 11 is a partial schematic diagram of another display panel according to an embodiment of the present disclosure. As shown in FIG. 11, the display panel includes pixel circuits 60 and a shift driving circuit 70, both of which are located at the driving layer 10. The shift driving circuit 70 includes cascaded shift register units 71, output terminals of the shift register units 71 are connected to the pixel circuits 60, and at least some of the dummy holes 20 are located between the shift driving circuit 70 and the pixel circuit array 60S. With such a configuration, the dummy holes 20 are closer to the pixel circuits 60, and the characteristic performance of the transistor at the edge position of the pixel circuit array 60S can be adjusted by using the dummy holes 20, thereby enabling the characteristic of the transistor at the edge position in the pixel circuit array 60S to be consistent with the characteristic of the transistor at the middle position, and enabling the performance of the pixel circuits 60 at different positions in the pixel circuit array 60S to be substantially consistent, and thus ensuring the display uniformity. In addition, the dummy holes 20, as channels for discharging hydrogen gas in the dehydrogenation process, can also adjust the characteristic performance of the transistors in the nearby shift register units 71.

In some embodiments, FIG. 12 is a partial schematic diagram of another display panel according to an embodiment of the present disclosure. As shown in FIG. 12, the display panel includes a first region A1 and a second region A2, and a distance between the first region A1 and the pixel circuit array 60S is smaller than a distance between the second region A2 and the pixel circuit array 60S. The dummy holes 20 include first dummy holes 20-1 and second dummy holes 20-2. The first dummy holes 20-1 are located in the first region A1, and the second dummy holes 20-2 are located in the second region A2. A distribution density of the first dummy holes 20-1 is greater than a distribution density of the second dummy holes 20-2. The plurality of first dummy holes 20-1 are regularly or irregularly distributed in the first region A1, and the plurality of second dummy holes 20-2 are regularly or irregularly distributed in the second region A2. In the embodiments of the present disclosure, the distribution density of the dummy holes 20 in the region close to the pixel circuit array 60S is relatively large, and the distribution density of the dummy holes 20 in the region far away from the pixel circuit array 60S is relatively small, such that the plurality of first dummy holes 20-1 with a relatively large distribution density can serve as the main discharge channel of hydrogen gas, and the plurality of second dummy holes 20-2 with a relatively small distribution density serve as the auxiliary discharge channel of hydrogen gas, thereby improving the transistor characteristic at the edge position of the pixel circuit array 60S, enabling the transistor characteristic at the edge position of the pixel circuit array 60S to be consistent with the transistor characteristic at the middle position, and thus improving the display uniformity.

In some embodiments, as shown in FIG. 12, the display panel includes a first region A1 and a second region A2, and a distance between the first region A1 and the pixel circuit array is smaller than a distance between the second region A2 and the pixel circuit array. The dummy holes 20 include first dummy holes 20-1 and second dummy holes 20-2. The first dummy holes 20-1 are located in the first region A1, and the second dummy holes 20-2 are located in the second region A2. A spacing distance between two adjacent first dummy holes 20-1 in the first region A1 is smaller than a spacing distance between two adjacent second dummy holes 20-2 in the second region A2. Therefore, the distribution density of the first dummy holes 20-1 in the first region A1 is greater than the distribution density of the second dummy holes 20-2 in the second region A2. The plurality of first dummy holes 20-1 are used as the main discharge channel of hydrogen gas, and the plurality of second dummy holes 20-2 are used as the auxiliary discharge channel of hydrogen gas, so as to improve the transistor characteristic at the edge position of the pixel circuit array 60S.

In some embodiments, a spacing between adjacent first dummy holes 20-1 in the first region A1 is d1, where 4 μm≤d1≤6 μm. With such a configuration, under the condition that the hole size of the first dummy holes 20-1 is fixed, a relatively large number of first dummy holes 20-1 can be formed in a limited space, so as to ensure the requirement of hydrogen gas discharge.

In some embodiments, a spacing between adjacent second dummy holes 20-2 in the second region A2 is d2, where 9 μm≤d2≤12 μm. With such a configuration, a certain number of second dummy holes 20-2 can be arranged in the second region A2 to assist the first dummy holes 20-1 to jointly serve as the hydrogen gas discharge channel. Meanwhile, since the spacing distance between adjacent second dummy holes 20-2 is relatively large, traces can also be arranged between adjacent second dummy holes 20-2, so as to fully utilize the space to satisfy the wiring requirements.

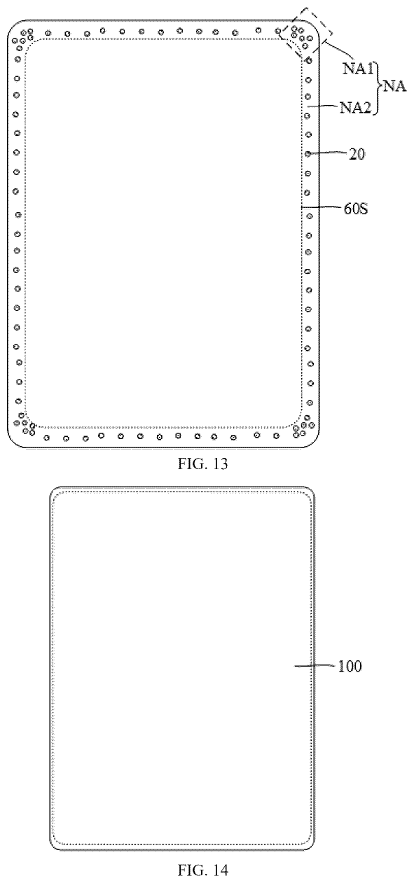

In some other embodiments, FIG. 13 is a schematic diagram of another display panel according to an embodiment of the present disclosure. As shown in FIG. 13, the display panel includes a non-display region NA surrounding the pixel circuit array 60S. The non-display region NA includes a corner non-display region NA1 and a straight-edge non-display region NA2. It can be seen that the display panel includes four corner non-display regions NA1 and four straight-edge non-display regions NA2. The distribution density of the dummy holes 20 in the corner non-display region NA1 is greater than the distribution density of the dummy holes 20 in the straight-edge non-display region NA2. Generally, peripheral driving circuits, such as shift driving circuits, are arranged in the straight-edge non-display region NA2, and the peripheral driving circuits need to occupy a relatively large area. The line positions in the corner non-display region NA1 will be relatively fewer. In the embodiments of the present disclosure, the distribution density of the dummy holes 20 in the corner non-display region NA1 is relatively large, which can minimize the occupation of the straight-edge non-display region NA2 while satisfying the requirement for discharging the hydrogen gas, so as to satisfy the requirement of a narrow bezel.

Based on the same inventive concept, an embodiment of the present disclosure further provides a display device. FIG. 14 is a schematic diagram of a display device according to an embodiment of the present disclosure. As shown in FIG. 14, the display device includes the display panel 100 provided by any embodiment of the present disclosure. The structure of the display panel 100 has been described in the above embodiments, and will not be repeated here. The display device according to some embodiments of the present disclosure may be, for example, an electronic device having a display function, such as a mobile phone, a tablet, a computer, a television, and a smart wearable product.

The above description just illustrates preferred embodiments of the present disclosure and is not intended to limit the present disclosure, and any modifications, equivalent substitutions, improvements and the like made within the spirit and principle of the present disclosure should be included within the protection scope of the present disclosure.

Finally, it should be noted that, the above embodiments are just used to illustrate the technical solutions of the present disclosure, but not to limit the same. Although the present disclosure has been described in detail with reference to the foregoing embodiments, those skilled in the art should understand that: the technical solutions described in the foregoing embodiments may still be modified, or some or all of the technical features may be equivalently substituted; and these modifications or substitutions do not make the essence of the corresponding technical solutions depart from the scope of the technical solutions in the embodiments of the present disclosure.

What is claimed is:

1. A display panel, comprising a substrate and a driving layer located on a side of the substrate,
wherein the driving layer comprises a dummy hole and a semiconductor structure, the dummy hole extends along a direction perpendicular to a plane of the substrate, the semiconductor structure at least partially surrounds the dummy hole, an inner wall of the dummy hole circumferentially exposes at least a portion of the semiconductor structure, and a bottom of the dummy hole is located at an insulating layer on a side of the semiconductor structure close to the substrate.

2. The display panel according to claim 1, wherein an orthographic projection of the semiconductor structure on the plane of the substrate is annular.

3. The display panel according to claim 2, wherein the semiconductor structure comprises an outer edge and an inner edge, the outer edge surrounds the inner edge, and the inner wall of the dummy hole exposes the inner edge; and
along a direction parallel to the plane of the substrate, a distance between the outer edge and the inner edge is d, where 0.5 μm≤d≤1 μm.

4. The display panel according to claim 2, wherein the semiconductor structure comprises an outer edge and an inner edge, the outer edge surrounds the inner edge, and the inner wall of the dummy hole exposes the inner edge; and
along a direction parallel to the plane of the substrate, a dimension of the outer edge is L, where 3.9 μm≤L≤6.8 μm.

5. The display panel according to claim 1, wherein a material of the semiconductor structure comprises silicon or indium gallium zinc oxide.

6. The display panel according to claim 1, wherein the insulating layer penetrated by the dummy hole is an inorganic insulating layer.

7. The display panel according to claim 1, wherein the dummy hole is filled with an insulating material.

8. The display panel according to claim 1, wherein a depth of the dummy hole is h, where 1.5 μm≤h≤1.6 μm.

9. The display panel according to claim 1, wherein the dummy hole comprises an orifice on a side away from the substrate; and
along the direction perpendicular to the plane of the substrate, a distance between the semiconductor structure and the bottom of the dummy hole is h1, and a distance between the semiconductor structure and the orifice of the dummy hole is h2, where h1<h2.

10. The display panel according to claim 1, wherein the driving layer comprises a first transistor, the first transistor comprises a semiconductor active layer, a gate electrode, a source electrode and a drain electrode, at least one of the source electrode and the drain electrode is connected to the semiconductor active layer through an opening, and the semiconductor active layer and the semiconductor structure are located in a same layer; and
the opening extends along the direction perpendicular to the plane of the substrate, the semiconductor active layer surrounds the opening, an inner wall of the opening circumferentially exposes a circle of the semiconductor active layer, and at least one of the source electrode and the drain electrode extends into the opening to contact the semiconductor active layer.

11. The display panel according to claim 10, wherein the driving layer comprises a pixel circuit, and the pixel circuit comprises the first transistor; and/or,
the driving layer comprises a shift driving circuit, and the shift driving circuit comprises the first transistor.

12. The display panel according to claim 10, wherein a depth of the opening is the same as a depth of the dummy hole along the direction perpendicular to the plane of the substrate.

13. The display panel according to claim 1, wherein the driving layer comprises a plurality of pixel circuits arranged in a pixel circuit array; and
a plurality of dummy holes are located at a periphery of the pixel circuit array.

14. The display panel according to claim 13, wherein the driving layer further comprises a shift driving circuit, the shift driving circuit comprises cascaded shift register units, and output terminals of the shift register units are connected to the plurality of pixel circuits; and
at least some of the plurality of dummy holes are located between the shift driving circuit and the pixel circuit array.

15. The display panel according to claim 13, wherein the display panel comprises a first region and a second region, and a distance between the first region and the pixel circuit array is smaller than a distance between the second region and the pixel circuit array;
the plurality of dummy holes comprise first dummy holes and second dummy holes, the first dummy holes are located in the first region, and the second dummy holes are located in the second region; and
a distribution density of the first dummy holes is greater than a distribution density of the second dummy holes.

16. The display panel according to claim 13, wherein the display panel comprises a first region and a second region, and a distance between the first region and the pixel circuit array is smaller than a distance between the second region and the pixel circuit array;
the plurality of dummy holes comprise first dummy holes and second dummy holes, the first dummy holes are located in the first region, and the second dummy holes are located in the second region; and
a spacing between adjacent first dummy holes is smaller than a spacing between adjacent second dummy holes.

17. The display panel according to claim 16, wherein the spacing between adjacent first dummy holes is d1, where 4 μm≤d1≤6 μm; and/or
the spacing between adjacent second dummy holes is d2, where 9 μm≤d2≤12 μm.

18. The display panel according to claim 13, wherein the display panel comprises a non-display region surrounding the pixel circuit array;
the non-display region comprises a corner non-display region and a straight-edge non-display region; and
a distribution density of dummy holes in the corner non-display region is greater than a distribution density of dummy holes in the straight-edge non-display region.

19. A display device, comprising a display panel,
wherein the display panel comprises a substrate and a driving layer located on a side of the substrate,
wherein the driving layer comprises a dummy hole and a semiconductor structure, the dummy hole extends along a direction perpendicular to a plane of the substrate, the semiconductor structure at least partially surrounds the dummy hole, an inner wall of the dummy hole circumferentially exposes at least a portion of the semiconductor structure, and a bottom of the dummy hole is located at an insulating layer on a side of the semiconductor structure close to the substrate.
